(19) United States
(12) Patent Application Publication
(10) Pub. No.: US 2025/0072238 A1
(43) Pub. Date: Feb. 27, 2025

(54) DISPLAY PANEL AND DISPLAY APPARATUS

(71) Applicants: Hefei Visionox Technology Co., Ltd., Hefei (CN); KunShan Go-Visionox Opto-Electronics Co., Ltd, Kunshan (CN)

(72) Inventors: Yuan YAO, Hefei (CN); Chung-Chun LEE, Hefei (CN); Yiming XIAO, Hefei (CN); Manli CHEN, Hefei (CN); Bo RAO, Hefei (CN); Liusong NI, Hefei (CN); Zihan WANG, Hefei (CN)

(73) Assignees: Hefei Visionox Technology Co., Ltd., Hefei (CN); KunShan Go-Visionox Opto-Electronics Co., Ltd, Kunshan (CN)

(21) Appl. No.: 18/734,197

(22) Filed: Jun. 5, 2024

Related U.S. Application Data
(63) Continuation of application No. PCT/CN2024/082661, filed on Mar. 20, 2024.

(30) Foreign Application Priority Data
Aug. 21, 2023 (CN) 202311054421.8
Dec. 29, 2023 (CN) 202311857204.2

(51) Int. Cl. H10K 59/131; H10K 59/122; H10K 59/126

(52) U.S. Cl. CPC H10K 59/131; H10K 59/122; H10K 59/126

(57) ABSTRACT

A display panel and a display apparatus. The display panel includes: a substrate; an isolation structure arranged on the substrate, the isolation structure enclosing and forming an isolation opening and a light-transmitting opening; a light-emitting unit being configured in the isolation opening; a conductive layer at least partially arranged on a side of the isolation structure away from the substrate; and a shielding layer arranged on the substrate, the shielding layer including a shielding portion, and an orthographic projection of the shielding portion on the substrate at least partially overlapping with an orthographic projection of the light-transmitting opening on the substrate.

### CROSS-REFERENCE TO RELATED APPLICATIONS

This application is a continuation application of International Application No. PCT/CN2024/082661, filed on Mar. 20, 2024, which claims priority to Chinese Patent Application No. 202311054421.8, entitled “DISPLAY PANEL AND DISPLAY APPARATUS” and filed on Aug. 21, 2023, and Chinese Patent Application No. 202311857204.2, entitled “DISPLAY PANEL AND DISPLAY APPARATUS” and filed on Dec. 29, 2023, the entire contents of which are incorporated herein by reference.

### TECHNICAL FIELD

The present application relates to the technical field of display devices, and in particular, to a display panel and a display apparatus.

### BACKGROUND

An organic light emitting display (OLED) and a flat display apparatus based on a light emitting diode (LED) technology are widely used in various consumer electronic products such as mobile phones, TVs, notebook computers, and desktop computers due to advantages such as high image quality, power saving, a thin body, and a wide range of applications, becoming the mainstream in display apparatuses.

However, operational performance of current OLED display products needs to be improved.

### SUMMARY

Embodiments of the present application provide a display panel and a display apparatus, intended to improve operational performance of the display panel.

An embodiment of a first aspect of the present application provides a display panel, including: a substrate; an isolation structure arranged on the substrate, the isolation structure enclosing and forming an isolation opening and a light-transmitting opening; a light-emitting unit being configured in the isolation opening; a conductive layer at least partially arranged on a side of the isolation structure away from the substrate; and a shielding layer arranged on the substrate, the shielding layer including a shielding portion, and an orthographic projection of the shielding portion on the substrate at least partially overlapping with an orthographic projection of the light-transmitting opening on the substrate.

An embodiment of the first aspect of the present application further provides a display panel, including: a substrate; an isolation structure arranged on a side of the substrate, the isolation structure enclosing and forming an isolation opening and a light-transmitting opening, the isolation opening being configured to accommodate a light-emitting unit; a conductive layer at least partially arranged on a side of the isolation structure away from the substrate; and a shielding layer, the shielding layer including a shielding portion, and an orthographic projection of the shielding portion on the substrate at least partially overlapping with an orthographic projection of the light-transmitting opening on the substrate, wherein the shielding layer is arranged in the substrate, or the shielding layer is arranged on the substrate and located between the substrate and the isolation structure.

An embodiment of a second aspect of the present application further provides a display apparatus, including the display panel in any one of the above embodiments in the first aspect.

In the display panel provided in the embodiments of the present application, the display panel includes a substrate, an isolation structure, and a shielding layer. The isolation structure is configured to form an isolation opening so that a light-emitting unit may be arranged in the isolation opening. The isolation structure is further configured to form a light-transmitting opening to improve light transmittance performance of the display panel. However, the formation of the light-transmitting opening in the isolation structure may easily cause generation of parasitic capacitance between conductive layers on upper and lower sides of the isolation structure at the light-transmitting opening. In the present application, the shielding portion is arranged, and the orthographic projection of the shielding portion on the substrate at least partially overlaps with the orthographic projection of the light-transmitting opening on the substrate, so that the shielding portion can function as a shielding layer, thereby ameliorating the parasitic capacitance generated in the display panel and improving operational performance of the display panel.

### BRIEF DESCRIPTION OF THE DRAWINGS

Other features, objectives, and advantages of the present application will become more apparent upon reading the following detailed description of non-limiting embodiments with reference to the accompanying drawings, in which identical or similar reference numerals refer to identical or similar features.

FIG. 1 is a schematic structural diagram of a display panel according to an embodiment of the present application;

FIG. 2 is a sectional view taken along A-A in FIG. 1 in an example;

FIG. 3 is a sectional view taken along A-A in FIG. 1 in another example;

FIG. 4 is a sectional view taken along A-A in FIG. 1 in yet another example;

FIG. 5 is a sectional view taken along A-A in FIG. 1 in still another example; and

FIG. 6 is a sectional view taken along A-A in FIG. 1 in a further example.

### REFERENCE SIGNS

10. display panel;
100. substrate; 110. base; 120. first electrode layer; 121. first electrode; 130. planarization layer; 140. insulating layer; 141. pixel opening; 142. reserved opening;
200. isolation structure; 210. isolation opening; 220. light-transmitting opening; 201. first sublayer; 202. second sublayer; 203. third sublayer;
300. shielding layer; 310. shielding portion; 320. bridging line;
400. conductive layer; 410. first sub-conductive layer; 411. first signal line; 420. second sub-conductive layer; 421. second signal line;
500. light-emitting unit;
600. second electrode layer; 610. second electrode;
700. power signal line;
X. first direction; Y. second direction.

### DETAILED DESCRIPTION

Features and exemplary embodiments in various aspects of the present application will be described in detail below. In the following detailed description, numerous specific details are set forth in order to provide a thorough understanding of the present application. However, it will be apparent to those skilled in the art that the present application can be implemented without some of these specific details. The following description of the embodiments is merely to provide a better understanding of the present application by illustrating the examples of the present application. In the drawings and the following description, at least part of well-known structures and technologies are not shown in order to avoid unnecessarily obscuring the present application. Further, for clarity, sizes of part of the structures may be exaggerated. Furthermore, the features, structures, or characteristics described below may be combined in any suitable manner in one or more embodiments.

In the description of the present application, it should be noted that, unless otherwise stated, the meaning of “a plurality” is two or more; the orientation or positional relationship indicated by the terms “upper”, “lower”, “left”, “right”, “inner”, “outer”, and the like is merely for the purpose of describing the present application and simplifying the description, and is not intended to indicate or imply that the apparatus or element referred to has a particular orientation, is constructed and operated in a particular orientation, and therefore cannot be understood to be a limitation on the present application. Moreover, the terms “first”, “second”, and the like are for descriptive purposes only and cannot be construed as indicating or implying relative importance.

The terms of orientation in the following description are all directions shown in the drawings and are not intended to limit specific structures of the present application. In the description of the present application, it is to be further noted that unless specifically stated and limited, the terms “mount” and “connect” should be understood in a broad sense, such as, a fixed connection, a detachable connection, or an integral connection; or a direct connection, or an indirect connection. For those of ordinary skill in the art, the specific meanings of the above terms in the present application may be understood depending on specific situations.

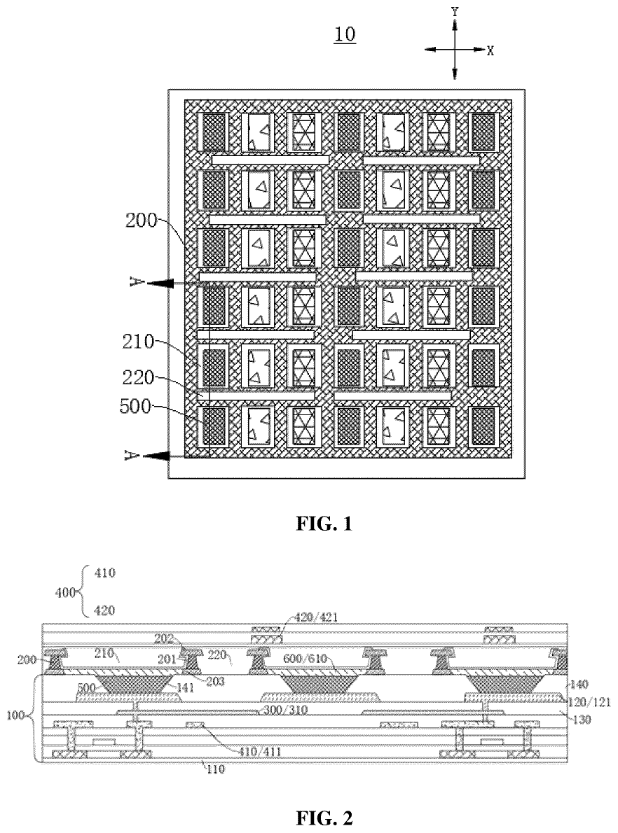

For better understanding of the present application, a display panel and a display apparatus according to embodiments of the present application will be described in detail below with reference to FIG. 1 to FIG. 4.

Patents PCT/CN2023/134518, 202310759370.2, 202310740412.8, 202310707209.0, and 202311346196.5 disclose relevant technical solutions for isolation structures, the contents of which are incorporated into the present application by reference.

FIG. 1 is a schematic structural diagram of a display panel 10 according to an embodiment of the present application. FIG. 2 is a sectional view taken along A-A in FIG. 1 in an example.

As shown in FIG. 1 and FIG. 2, an embodiment of a first aspect of the present application provides a display panel 10, including a substrate 100, an isolation structure 200, and a shielding layer 300. The isolation structure 200 is arranged on the substrate 100. The isolation structure 200 encloses and forms an isolation opening 210 and a light-transmitting opening 220. The isolation opening 210 is configured to accommodate a light-emitting unit 500. The shielding layer 300 is arranged on the substrate 100. The shielding layer 300 includes a shielding portion 310. An orthographic projection of the shielding portion 310 on the substrate 100 at least partially overlaps with an orthographic projection of the light-transmitting opening 220 on the substrate 100.

In the display panel 10 provided in this embodiment of the present application, the display panel 10 includes a substrate 100, an isolation structure 200, and a shielding layer 300. The isolation structure 200 is configured to form an isolation opening 210 so that a light-emitting unit 500 may be arranged in the isolation opening 210. The isolation structure 200 is further configured to form a light-transmitting opening 220 to improve light transmittance of the display panel 10. However, the formation of the light-transmitting opening 220 in the isolation structure 200 may easily cause generation of parasitic capacitance between conductive layers 400 on upper and lower sides of the isolation structure 200 at the light-transmitting opening 220. In the present application, the shielding portion 310 is arranged, and the orthographic projection of the shielding portion 310 on the substrate 100 at least partially overlaps with the orthographic projection of the light-transmitting opening 220 on the substrate 100, so that the shielding portion 310 can function as a shielding layer, thereby ameliorating the parasitic capacitance generated in the display panel 10 and improving operational performance of the display panel 10.

In some optional embodiments, the display panel 10 further includes a conductive layer 400, the conductive layer 400 includes a second sub-conductive layer 420 located on a side of the isolation structure 200 facing away from the substrate 100, the second sub-conductive layer 420 includes a second signal line 421, and an orthographic projection of the second signal line 421 on the substrate 100 is misaligned with the orthographic projection of the light-transmitting opening 220 on the substrate 100.

In such optional embodiments, the orthographic projection of the second signal line 421 on the substrate 100 is at least partially misaligned with the orthographic projection of the light-transmitting opening 220 on the substrate 100, ameliorating an influence of the second signal line 421 on light transmittance.

Optionally, the conductive layer 400 further includes a first sub-conductive layer 410 located on a side of the shielding layer 300 facing the substrate 100, the first sub-conductive layer 410 includes a first signal line 411, and an orthographic projection of the first signal line 411 on the substrate 100 at least partially overlaps with the orthographic projection of the second signal line 421 on the substrate 100. As a result, parasitic capacitance is easily generated between the first signal line 411 and the second signal line 421. Through the arrangement of the shielding portion 310, the shielding portion 310 can play a shielding role, ameliorating parasitic capacitance between the first signal line 411 and the second signal line 421.

Optionally, the orthographic projection of the first signal line 411 on the substrate 100 is misaligned with the orthographic projection of the light-transmitting opening 220 on the substrate 100, ameliorating an influence of the first signal line 411 on the light transmittance.

The first signal line 411 is arranged in a variety of manners. The first signal line 411 may include at least one of a data line, a scanning line, and a voltage reference line, and the second signal line 421 may include one of signal lines such as a touch trace, as long as the first signal line 411 and the second signal line 421 can transmit currents and comply with the above positional relationship.

The substrate 100 is arranged in a variety of manners. The substrate 100 includes a base 110 and a first conductive layer, a second conductive layer, and a third conductive layer that are arranged on a side of the base 110 and stacked. Insulating layers are arranged between adjacent conductive layers. Exemplarily, a pixel driving circuit arranged on an array substrate includes a transistor and a storage capacitor. The transistor includes a semiconductor, a gate, a source, and a drain. The storage capacitor includes a first plate and a second plate. As an example, the gate and the first plate may be located on the first conductive layer, the second plate may be located on the second conductive layer, and the source and the drain may be located on the third conductive layer.

Optionally, the substrate 100 further includes a first electrode layer 120 arranged on the base 110, the first electrode layer 120 may include first electrodes 121 corresponding to the isolation openings 210, the first electrodes 121 are arranged corresponding to the light-emitting units 500, and the first electrodes 121 are located on sides of the light-emitting units 500 facing the base 110.

The isolation structure 200 is arranged in a variety of manners. The isolation structure 200 may include a first sublayer 201 and a second sublayer 202 that are sequentially stacked in a direction away from the substrate 100. An orthographic projection of the first sublayer 201 on the substrate 100 is located within an orthographic projection of the second sublayer 202 on the substrate 100.

In such optional embodiments, the orthographic projection of the first sublayer 201 on the substrate 100 is located within the orthographic projection of the second sublayer 202 on the substrate 100, so that a recess is formed on a side of the second sublayer 202 facing the substrate 100. When a light-emitting material is evaporated, the light-emitting material may be broken near the isolation structure 200 to form light-emitting units 500 independent of each other, thereby omitting a tight mask evaporation process and simplifying a manufacturing process of the display panel 10.

Optionally, the display panel 10 further includes a second electrode layer 600, and the second electrode layer 600 includes second electrodes 610 located on sides of the light-emitting units 500 facing away from the substrate 100. Optionally, at least part of the isolation structure 200 is made of a conductive material, and the second electrode 610 and the isolation structure 200 are conductively connected, so that a plurality of second electrodes 610 can be interconnected through the isolation structure 200 to form an entire-surface electrode. Optionally, the first sublayer 201 is made of a conductive material, and the second electrode 610 and the first sublayer 201 are electrically connected to each other. Optionally, the second sublayer 202 may also be made of a conductive material, to increase a distribution area of conductive parts in the isolation structure 200 and reduce overall resistance of the second electrode 610.

Optionally, the isolation structure 200 may further include a third sublayer 203 located on a side of the first sublayer 201 facing the substrate 100, and the orthographic projection of the first sublayer 201 on the substrate 100 is located within an orthographic projection of the third sublayer 203 on the substrate 100. Through the arrangement of the third sublayer 203, when the first sublayer 201 is side-etched so that the orthographic projection of the first sublayer 201 on the substrate 100 is located within the orthographic projection of the second sublayer 202 on the substrate 100, the third sublayer 203 may provide protection for a material located under the third sublayer 203 to prevent damage to a layer structure under the third sublayer 203. Optionally, the third sublayer 203 is made of a conductive material, and the second electrode 610 is further electrically connected to the third sublayer 203 to increase an area of contact between the second electrode 610 and the isolation structure 200 and reduce the overall resistance of the second electrode 610.

The shielding layer 300 is arranged in a variety of manners. As described above, when the display panel 10 includes the first electrode layer 120, the shielding layer 300 may be arranged on a side of the first electrode layer 120 facing the base 110, or the shielding layer 300 may be arranged on a side of the first electrode layer 120 facing away from the base 110.

Optionally, the shielding layer 300 is arranged on the side of the first electrode layer 120 facing the base 110, a plurality of shielding portions 310 may be provided, and at least one shielding portion 310 of the plurality of shielding portions 310 may be connected to the first electrode 121, so that the first electrode 121 may be connected to the pixel driving circuit through the shielding portion 310. The shielding portion 310 can shield the first signal line 411 and the second signal line 421, and the shielding portion 310 can also be configured to connect the first electrode 121 and the pixel driving circuit, which can enrich functions of the shielding portion 310 and simplify a structure of the display panel 10.

Optionally, the shielding portions 310 are connected to the first electrodes 121, so that structures and shapes of the shielding portions 310 tend to be consistent, further simplifying the structure of the display panel 10.

Optionally, a planarization layer 130 is arranged between the base 110 and the first electrode layer 120, and the shielding layer 300 is arranged on a side of the planarization layer 130 facing the base 110. The planarization layer 130 is arranged between the shielding portions 310 and the first electrode layer 120, which can alleviate the problem of a short-circuit connection between the shielding portion 310 and the first electrode 121.

As described above, when the substrate 100 includes the first conductive layer, the second conductive layer, and the third conductive layer, the shielding layer 300 is arranged on a side of the third conductive layer facing away from the base 110.

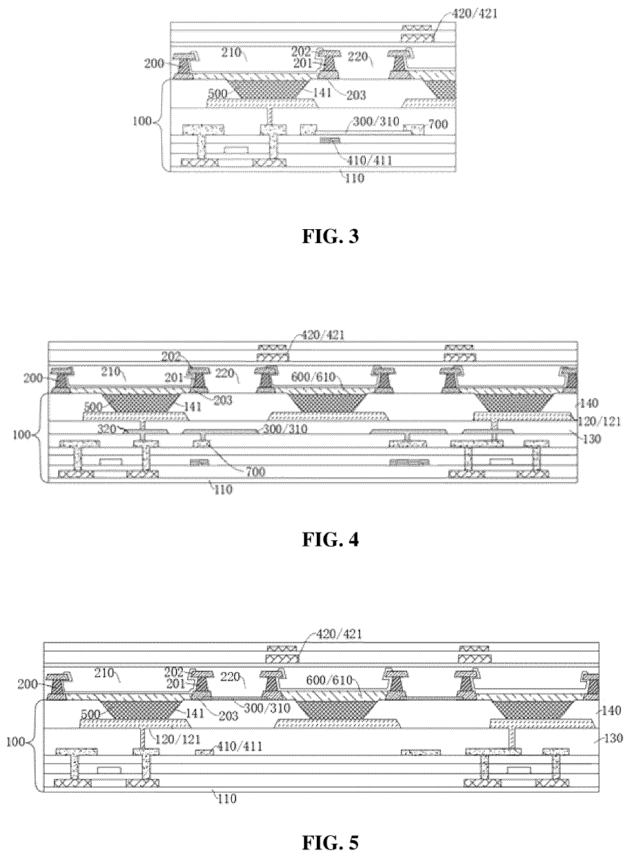

In some other optional embodiments, as shown in FIG. 1 and FIG. 3, the substrate 100 further includes a power signal line 700, and at least one shielding portion 310 and the power signal line 700 are electrically connected to each other. Therefore, the shielding portion 310 may be configured to transmit power signals, thereby increasing a distribution area of the power signal line 700 and reducing resistance of the power signal line 700. At the same time, the power signal line 700 provides stable potential for the shielding portion 310 to shield signals. The power signal line 700 is, for example, a driving power voltage signal line. For example, the power signal line 700 is configured to provide a positive voltage. The power signal line 700 is connected to the first electrode 121 through the pixel driving circuit to drive the first electrode 121.

Optionally, an orthographic projection of the power signal line 700 on the base 110 is misaligned with the orthographic projection of the light-transmitting opening 220 on the base 110, to ameliorate an influence of the power signal line 700 on the light transmittance.

Optionally, the shielding portion 310 and the power signal line 700 are on a same layer and are in contact with each other, so that the shielding portion 310 can carry a stable voltage signal, thereby alleviating the problem of parasitic capacitance.

The power signal line 700 may be at least one of a driving power voltage signal line, a voltage reference line, a ground signal line, and a low-level power voltage signal line. For example, the power signal line 700 may be a driving power voltage signal line, so that the power signal line 700 can have more stable potential. The power signal line 700 having stable potential means that a voltage thereof is stable within one frame of display time period. The driving power voltage signal line may be a VSS signal line or a VDD signal line.

Optionally, at least two power signal lines 700 are distributed at intervals, and the shielding portion 310 is connected between two adjacent power signal lines 700, so as to further increase a distribution area of the shielding portion 310 and reduce the resistance of the power signal line 700.

Optionally, the shielding portion 310 may be located between two adjacent power signal lines 700 connected thereto. Alternatively, in other embodiments, the orthographic projection of the shielding portion 310 on the substrate 100 partially overlaps with an orthographic projection of at least one of the two adjacent power signal lines 700 connected thereto on the substrate 100, to increase an area of contact between the shielding portion 310 and the power signal line 700.

In some other embodiments, as shown in FIG. 1 and FIG. 4, the shielding portion 310 is located on a side of the power signal line 700 facing away from the base 110, and the shielding portion 310 is connected to the power signal line 700 by a via hole. In such embodiments, the shielding portion 310 is directly connected to the power signal line 700 by the via hole, which can improve stability of the connection between the shielding portion 310 and the power signal line 700, thereby enabling the shielding portion 310 to provide a stable shielding effect.

Optionally, still referring to FIG. 4, at least part of an orthographic projection of the power signal line 700 on the base 110 is located within an orthographic projection of the shielding portion 310 on the base 110. On the one hand, a distance between the power signal line 700 and the shielding portion 310 can be reduced, and the power signal line 700 and the shielding portion 310 can be connected by drilling a hole along a thickness direction of the display panel. On the other hand, a size of the shielding portion 310 can be increased, and the shielding effect of the shielding portion 310 can be improved.

Optionally, as described above, the power signal line 700 may be a driving power voltage signal line, and then the substrate 100 includes a bridging line 320 connecting the first electrode 121 and the pixel driving circuit, and the shielding portion 310 and the bridging line 320 are arranged on a same layer. The shielding portion 310 is located on, for example, a fourth conductive layer. The fourth conductive layer is located on a side of the third conductive layer facing away from the base 110, so that the bridging line 320 and the shielding portion 310 can be manufactured in a same process step, which can simplify the manufacturing process of the display panel.

Optionally, the shielding portion 310 and the bridging line 320 are insulated from each other. In this case, the shielding portion 310 may be connected to the power signal line 700. Alternatively, in other embodiments, the shielding portion 310 and the bridging line 320 may be connected to each other.

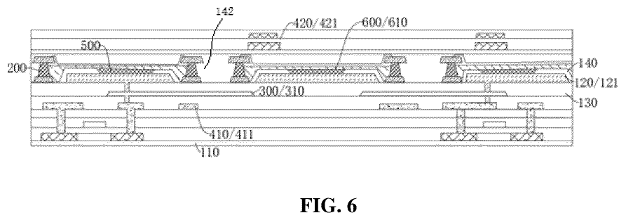

In some other optional embodiments, as shown in FIG. 1 and FIG. 5, the shielding layer 300 is arranged on a side of the isolation structure 200 facing the base 110, orthographic projections of the shielding portion 310 and the isolation structure 200 on the substrate 100 at least partially overlap, and the shielding portion 310 and the isolation structure 200 are electrically connected to each other.

In such optional embodiments, the shielding layer 300 is arranged on the side of the isolation structure 200 facing the substrate 100 and overlaps with the orthographic projection of the isolation structure 200 on the substrate 100, so that the shielding portion 310 and the isolation structure 200 are electrically connected to each other, which can reduce overall resistance of the first electrode 121.

Optionally, the shielding layer 300 and the isolation structure 200 are arranged adjacently along a thickness direction, and the shielding portion 310 and the isolation structure 200 are in direct contact, which can increase an area of contact between the shielding portion 310 and the isolation structure 200.

As described above, when the isolation structure 200 includes the first sublayer 201 and the second sublayer 202, the shielding portion 310 may be electrically connected to the first sublayer 201, and the shielding portion 310 may be located on the side of the first sublayer 201 facing the substrate 100. For example, the shielding portion 310 is located on the side of the first sublayer 201 facing the substrate 100 and is in contact with the first sublayer 201.

When the isolation structure 200 further includes a third sublayer 203 arranged on the side of the first sublayer 201 facing the substrate 100, the shielding portion 310 may be electrically connected to the third sublayer 203. For example, the shielding portion 310 is located on the side of the third sublayer 203 facing the substrate 100 and is in direct contact with the first sublayer 201.

Optionally, the display panel 10 further includes an insulating layer 140, the insulating layer 140 is arranged on the substrate 100, the insulating layer 140 is provided with a pixel opening 141, an orthographic projection of the pixel opening 141 on the substrate 100 is located within an orthographic projection of the isolation opening 210 on the substrate 100, and the pixel opening 141 is configured to accommodate the light-emitting unit 500. Through the arrangement of the insulating layer 140, a short-circuit connection between the isolation structure 200 and the first electrode 121 can be ameliorated.

Optionally, when the display panel 10 further includes an insulating layer 140 and the insulating layer 140 includes a pixel opening 141, the pixel opening 141 is located in the isolation opening 210, and the light-emitting unit 500 in the isolation opening 210 is located in the pixel opening 141.

Optionally, each first electrode 121 is exposed from the pixel opening 141, so that the first electrode 121 can interact with the second electrode 610 to cause the light-emitting unit 500 to emit light for display.

The insulating layer 140 is arranged in a variety of manners. For example, as shown in FIG. 6, the insulating layer 140 edges each first electrode 121. The first electrode 121 has an effective region and an edge region arranged around the effective region. The insulating layer 140 includes a plurality of insulating portions. Each insulating portion covers the edge region of each first electrode 121 and allows the effective region to be exposed from the pixel opening 141. The effective region determines a light-emitting area, and the edge region is covered by the insulating layer 140 to ameliorate the short-circuit connection between the isolation structure 200 and the first electrode 121. In other words, in such optional embodiments, the insulating layer 140 is provided with a reserved opening 142, at least part of the substrate 100 is exposed from the reserved opening 142, and the isolation structure 200 is arranged on the substrate 100 exposed from the reserved opening 142. The reserved opening 142 is formed between adjacent insulating portions, so that the isolation structure 200 can be arranged on the substrate 100 through a gap between the adjacent insulating portions.

In some other optional embodiments, the insulating layer 140 is a pixel defining layer, and the isolation structure 200 is arranged on a side of the pixel defining layer facing away from the substrate 100. The isolation structure 200 is arranged on the side of the pixel defining layer facing away from the substrate 100, that is, the isolation structure 200 and the first electrode 121 are arranged in different layers, which can better ameliorate the short-circuit connection between the isolation structure 200 and the first electrode 121.

There are many choices of materials for the shielding portion 310. For example, the material of the shielding portion 310 includes at least one of indium tin oxide and indium zinc oxide, so that the shielding portion 310 has good transmittance and also has good conductivity.

In some optional embodiments, the orthographic projection of the light-transmitting opening 220 on the substrate 100 is located within the orthographic projection of the shielding portion 310 on the substrate 100, so that the light-transmitting opening 220 can be completely blocked by the shielding portion 310, which better alleviates the problem of parasitic capacitance.

In some optional embodiments, a plurality of light-transmitting openings 220 are provided, and the plurality of light-transmitting openings 220 are distributed at intervals. Each light-transmitting opening 220 is correspondingly provided with the shielding portion 310. “Each light-transmitting opening 220 is correspondingly provided with the shielding portion 310” means that the orthographic projection of each light-transmitting opening 220 on the substrate 100 can at least partially overlap with the orthographic projection of the at least one shielding portion 310 on the substrate 100. Through the arrangement of the plurality of light-transmitting openings 220, the light transmittance of the display panel 10 can be improved.

Optionally, a plurality of light-emitting units 500 are provided, the plurality of light-emitting units 500 are distributed in rows and columns along a first direction X and a second direction Y, the light-transmitting opening 220 is located between two adjacent rows of light-emitting units 500, the first direction X is a row direction, the second direction Y is a column direction, and a same light-transmitting opening 220 overlaps with two or more of the light-emitting units 500 along the column direction. That is, one light-transmitting opening 220 is arranged corresponding to a plurality of light-emitting units 500, which can increase a distribution area of the light-transmitting opening 220 and further improve the light transmittance of the display panel 10.

An embodiment of the first aspect of the present application further provides a display panel 10, including: a substrate 100; an isolation structure 200 arranged on a side of the substrate 100, the isolation structure 200 enclosing and forming an isolation opening 210 and a light-transmitting opening 220, the isolation opening 210 being configured to accommodate a light-emitting unit 500; and a shielding layer 300, the shielding layer 300 including a shielding portion 310, and an orthographic projection of the shielding portion 310 on the substrate 100 at least partially overlapping with an orthographic projection of the light-transmitting opening 220 on the substrate 100, wherein the shielding layer 300 is arranged in the substrate 100, or the shielding layer 300 is arranged on the substrate 100 and located between the substrate 100 and the isolation structure 200.

Optionally, as described above, when the substrate 100 includes the base 110 and the first electrode layer 120, the shielding layer 300 may be arranged on a side of the first electrode layer 120 facing the base 110, or the shielding layer 300 may be arranged on a side of the first electrode layer 120 facing away from the base 110. Alternatively, the shielding layer 300 may be arranged on a same layer as the first electrode layer 120.

The substrate 100, the isolation structure 200, and the shielding layer 300 are arranged as described in the above embodiments of the display panel 10. Details are not described herein again.

An embodiment of a second aspect of the present application further provides a display apparatus, including the display panel 10 in any one of the above embodiments in the first aspect. Since the display apparatus provided in the embodiment of the second aspect of the present application includes the display panel 10 in any one of the above embodiments in the first aspect, the display apparatus provided in the embodiment of the second aspect of the present application has the beneficial effects of the display panel 10 in any one of the above embodiments in the first aspect. Details are not described herein again.

The display apparatus in the embodiments of the present application includes, but is not limited to, a mobile phone, a personal digital assistant (PDA), a tablet computer, an e-book, a television, an access control, a smart fixed phone, a console, and other devices with a display function.

Although the present application has been described with reference to the preferred embodiments, various modifications may be made thereto and components may be replaced with equivalents without departing from the scope of the present application. In particular, the technical features mentioned in various embodiments can be combined in any manner provided that there is no structural conflict. The present application is not limited to the specific embodiments disclosed herein, but includes all technical solutions falling into the protection scope of the claims.

What is claimed is:

1. A display panel, comprising:
a substrate;
an isolation structure arranged on a side of the substrate, the isolation structure enclosing and forming an isolation opening and a light-transmitting opening;
a light-emitting unit being configured in the isolation opening;
a conductive layer at least partially arranged on a side of the isolation structure away from the substrate; and
a shielding layer arranged on the substrate, the shielding layer comprising a shielding portion, and an orthographic projection of the shielding portion on the substrate at least partially overlapping with an orthographic projection of the light-transmitting opening on the substrate.

2. The display panel of claim 1, wherein the conductive layer comprises a second sub-conductive layer located on a side of the isolation structure facing away from the substrate, the second sub-conductive layer comprises a second signal line, and an orthographic projection of the second signal line on the substrate is misaligned with the orthographic projection of the light-transmitting opening on the substrate.

3. The display panel of claim 2, wherein the conductive layer further comprises a first sub-conductive layer located on a side of the isolation structure facing the substrate, the first sub-conductive layer comprising a first signal line, and an orthographic projection of the first signal line on the substrate at least partially overlapping with the orthographic projection of the second signal line on the substrate,
wherein the orthographic projection of the first signal line on the substrate is misaligned with the orthographic projection of the light-transmitting opening on the substrate,
wherein the first signal line comprises at least one of a data line, a scanning line, a power signal line, and a voltage reference line, and
wherein the second signal line comprises a touch trace.

4. The display panel of claim 1, wherein the substrate comprises a base and a first electrode layer arranged on the base, the first electrode layer comprising a plurality of first electrodes distributed at intervals, and the shielding layer is arranged on a side of the first electrode layer facing the base.

5. The display panel of claim 4, wherein a plurality of shielding portions are provided, and at least one of the shielding portions is electrically connected to the first electrode, and
wherein each of the shielding portions is connected to a corresponding one of the first electrodes.

6. The display panel of claim 5, wherein a planarization layer is arranged between the base and the first electrode layer, and the shielding layer is arranged on a side of the planarization layer facing the base.

7. The display panel of claim 4, wherein the substrate further comprises power signal lines, and at least one of the shielding portions and at least one of the power signal lines are electrically connected to each other,
wherein an orthographic projection of the power signal line on the base is misaligned with an orthographic projection of the light-transmitting opening on the base.

8. The display panel of claim 7, wherein the shielding portion and the power signal line are arranged on a same layer and are in contact with each other,
wherein at least two of the power signal lines are distributed at intervals, and the shielding portion is connected between two adjacent power signal lines, and
wherein the orthographic projection of the shielding portion on the substrate partially overlaps with an orthographic projection of at least one of the two adjacent power signal lines connected thereto on the substrate.

9. The display panel of claim 7, wherein the shielding portion is located on a side of the power signal line facing away from the base, and the shielding portion is connected to the power signal line by a via hole, and
wherein at least part of an orthographic projection of the power signal line on the base is located within an orthographic projection of the shielding portion on the base.

10. The display panel of claim 8, further comprising a pixel driving circuit, the substrate comprising a bridging line connecting the first electrode and the pixel driving circuit, and the shielding portion and the bridging line being on a same layer and insulated from each other.

11. The display panel of claim 5, further comprising a pixel driving circuit, the substrate comprising a bridging line connecting the first electrode and the pixel driving circuit, and the shielding portion and the bridging line being electrically connected to each other.

12. The display panel of claim 1, wherein the shielding layer is arranged on a side of the isolation structure facing the substrate, orthographic projections of the shielding portion and the isolation structure on the substrate at least partially overlap, and the shielding layer and the isolation structure are electrically connected to each other.

13. The display panel of claim 12, wherein the isolation structure comprises a first sublayer and a second sublayer sequentially stacked in a direction away from the substrate, an orthographic projection of the first sublayer on the substrate is located within an orthographic projection of the second sublayer on the substrate, and the shielding portion is arranged on a side of the first sublayer facing the substrate.

14. The display panel of claim 13, wherein the isolation structure further comprises a third sublayer arranged on the side of the first sublayer facing the substrate, the orthographic projection of the first sublayer on the substrate is located within an orthographic projection of the third sublayer on the substrate, and the shielding portion is arranged on a side of the third sublayer facing the substrate and is electrically connected to the third sublayer.

15. The display panel of claim 1, further comprising: an insulating layer arranged on the substrate, the insulating layer being provided with a pixel opening, an orthographic projection of the pixel opening on the substrate being located within an orthographic projection of the isolation opening on the substrate, and the pixel opening being configured to accommodate the light-emitting unit, and
wherein the insulating layer is a pixel defining layer, and the isolation structure is arranged on a side of the pixel defining layer facing away from the substrate.

16. The display panel of claim 15, wherein the insulating layer is provided with a reserved opening, at least part of the substrate is exposed from the reserved opening, and the isolation structure is arranged on the substrate exposed from the reserved opening.

17. The display panel of claim 1, wherein a material of the shielding portion comprises at least one of indium tin oxide and indium zinc oxide; and/or
the orthographic projection of the light-transmitting opening on the substrate is located within the orthographic projection of the shielding portion on the substrate.

18. The display panel of claim 1, wherein a plurality of light-transmitting openings are distributed at intervals, and each of the light-transmitting openings is correspondingly provided with the shielding portion, and
wherein the display panel comprises a plurality of light-emitting units, the plurality of light-emitting units being distributed in rows and columns along a first direction and a second direction, the first direction being a row direction, the second direction being a column direction, the light-transmitting opening is located between two adjacent rows of light-emitting units, and a same light-transmitting opening overlaps with two or more of the light-emitting units along the column direction.

19. A display panel, comprising:
a substrate;
an isolation structure arranged on a side of the substrate, the isolation structure enclosing and forming an isolation opening and a light-transmitting opening, the isolation opening being configured to accommodate a light-emitting unit;
a conductive layer at least partially arranged on a side of the isolation structure away from the substrate; and
a shielding layer, the shielding layer comprising a shielding portion, and an orthographic projection of the shielding portion on the substrate at least partially overlapping with an orthographic projection of the light-transmitting opening on the substrate,
wherein the shielding layer is arranged in the substrate, or the shielding layer is arranged on the substrate and located between the substrate and the isolation structure.

20. A display apparatus, comprising the display panel of claim 1.
